(19) United States
(12) Patent Application Publication
(10) Pub. No.: US 2011/0172945 A1
(43) Pub. Date: Jul. 14, 2011

(54) METHOD FOR MONITORING BURN-IN PROCEDURE OF ELECTRONIC DEVICE

(75) Inventors: ZHI-HAI TIAN, Shenzhen City (CN); ZHAO-JIE CAO, Shenzhen City (CN); HUA DONG, Shenzhen City (CN)

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/877,996

(22) Filed: Sep. 8, 2010

(30) Foreign Application Priority Data
Jan. 14, 2010 (CN) 201010300308.X

(51) Int. Cl. G06F 19/00; G01R 31/00

(52) U.S. Cl. 702/119

(57) ABSTRACT

A method for monitoring a burn-in procedure of an electronic device is performed by a host computer, an external storage device, and a display device. The external storage device stores the burn-in procedure and a monitor procedure. The host computer copies the monitor procedure to the at least one electronic device and activates the monitor procedure. The monitor procedure activates the burn-in procedure for the electronic device and determines a state of the burn-in procedure. The monitor procedure then outputs a monitor result corresponding to the state of the burn-in procedure into the display device. The display device displays the monitor result.

### BACKGROUND

1. Technical Field

The present disclosure relates to a method for monitoring a burn-in procedure of an electronic device.

2. Description of Related Art

“Burn-in” is a process to detect particular components of electronic devices that would fail as a result of the initial, high-failure rate portion of the bathtub curve of component reliability. The particular components may include CPU, memory, and motherboard, for example. If the burn-in period is made sufficiently long, the electronic devices can then be trusted to be mostly free of further early failures once the burn-in process is complete. However, to monitor the “burn-in” for mass production of electronic devices may be time consuming.

### BRIEF DESCRIPTION OF THE DRAWINGS

FIG. 1 is a block diagram of one embodiment of an electronic device in communication with a display device, a host computer, and an external storage device.

FIG. 2 is a flowchart illustrating one embodiment of a method for monitoring a burn-in procedure of the electronic device of FIG. 1.

FIG. 3 is a flowchart illustrating a detailed procedure of block S20 of FIG. 2.

### DETAILED DESCRIPTION

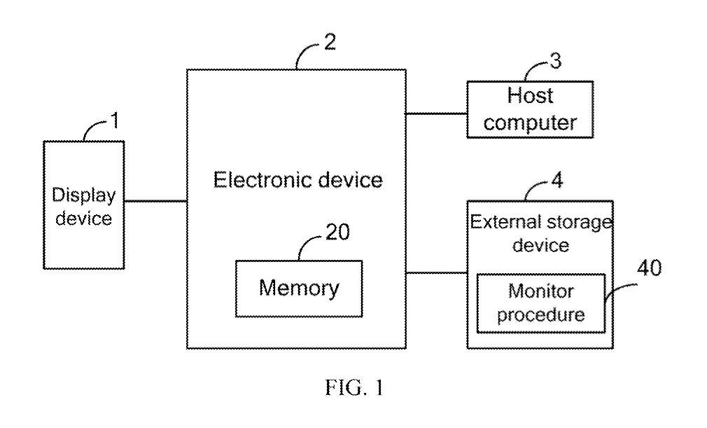

FIG. 1 is a block diagram of one embodiment of an electronic device 2 in communication with a display device 1, a host computer 3, and an external storage device 4. The display device 1 electronically connects with the electronic device 2. The electronic device 2 includes a memory 20. The memory 20 is a random access memory (RAM). The host computer 3 is capable of being in communication with the electronic device 2. In the embodiment, the host computer 3 connects with one electronic device 2. In the other embodiment, the host computer 3 may further connects with a number of electronic devices 2.

The external storage device 4 stores computerized code including a monitor procedure 40 and a burn-in procedure (not shown). The burn-in procedure is a method that details a process to burn-in for the electronic device 2. The monitor procedure 40 is a method used to monitor the burn-in procedure. The monitor procedure 40 is initially stored in the external storage device 4 and may not be installed in the electronic device 2. After the electronic device 2 is turned off, the monitor procedure 40 stored in the memory 20 may be automatically erased because the memory 20 is a RAM. As a result, an operating system (OS) of the electronic device 2 is not changed during the burn-in procedure.

The host computer 3 copies the monitor procedure 40 from the external storage device 4 to the memory 20 of the electronic device 2. The host computer 3 then activates the monitor procedure 40 stored in the memory 20 and activates the burn-in procedure for the electronic device 2. The monitor procedure 40 stored in the memory 20 determines a state of the burn-in procedure and outputs a monitor result corresponding to the state of the burn-in procedure into the display device 1. The display device 1 displays the monitor result.

The display device 1 displays a first state when the burn-in procedure is normally operative. The display device 1 displays a second state when the burn-in procedure is successfully complete. The display device 1 displays a third state when the burn-in procedure is failed or if the burn-in procedure is not activated. The display device 1 may include a lightning module (not shown) to display the monitor result. In the exemplary embodiment, the lightning module flashes to indicate the first state, lights continuously to indicate the second state, and stays off to indicate the third state.

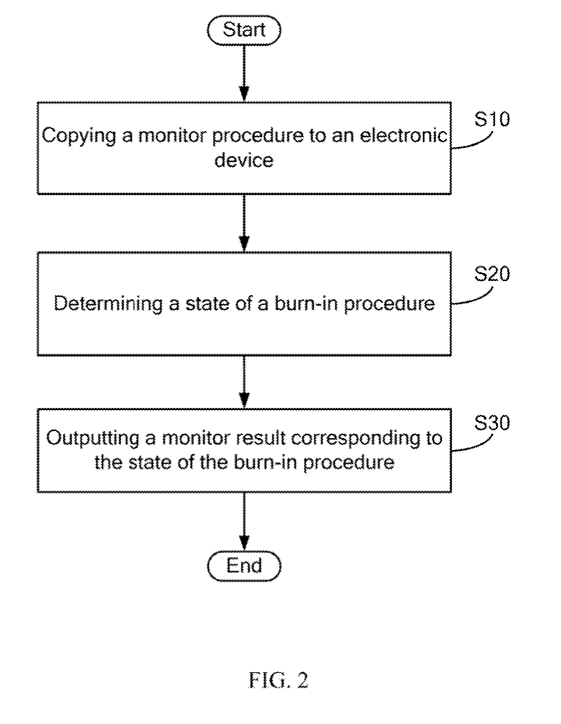

FIG. 2 is a flowchart illustrating one embodiment of a method for monitoring the burn-in procedure of the electronic device 2.

In block S10, the host computer 3 copies the monitor procedure 40 to the memory 20 and activates the monitor procedure 40.

In block S20, the monitor procedure 40 stored in the memory 20 activates the burn-in procedure for the electronic device 2 and determines the state of the burn-in procedure.

In block S30, the monitor procedure 40 stored in the memory 20 outputs the monitor result corresponding to the state of the burn-in procedure into the display device 1.

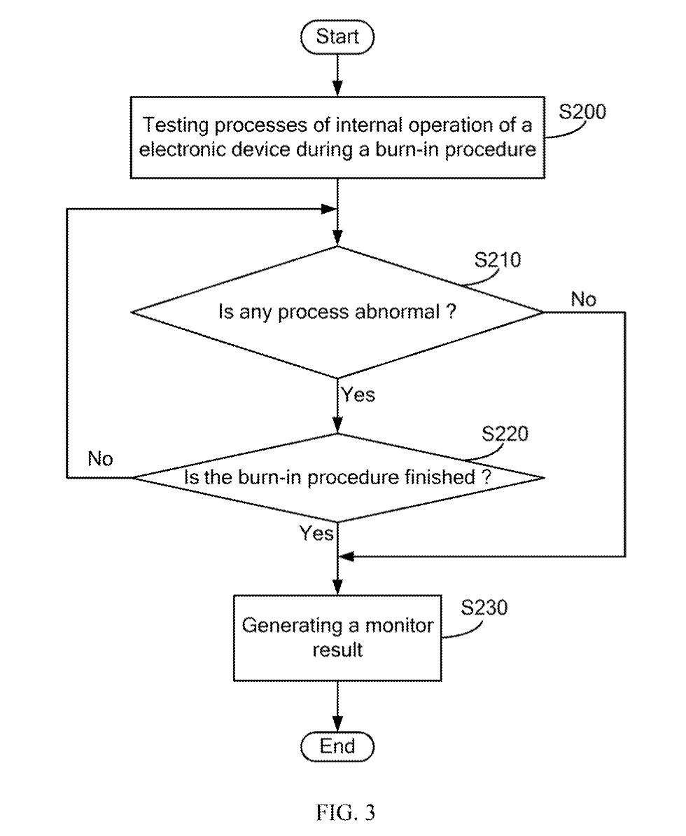

FIG. 3 is a flowchart illustrating a detailed procedure of block S20.

In block S200, the monitor procedure 40 stored in the memory 20 tests at least one process of internal operation of the electronic device 2 during a burn-in procedure.

In block S210, the monitor procedure 40 stored in the memory 20 determines whether the at least one process is abnormal. If the at least one process is normal, the block S230 is then implemented.

If the at least one process is abnormal, in block S220, the monitor procedure 40 stored in the memory 20 determines whether the burn-in procedure is finished. If the burn-in procedure is not finished, block S210 is repeated.

In block S230, the monitor procedure 40 stored in the memory 20 generates the monitor result corresponding to the state of the burn-in procedure. If the at least one process is normal, the monitor procedure 40 stored in the memory 20 determines that the burn-in procedure is successfully complete. If the at least one process is abnormal, the monitor procedure 40 stored in the memory 20 determines that the burn-in procedure is failed.

The present disclosure provides a method for automatically monitor a burn-in procedure of an electronic device. The hours of operators for monitoring the burn-in procedure may be saved.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A computer-implemented method for monitoring a burn-in procedure of an electronic device, the electronic device being connected with a host computer, and an external storage device storing a monitor procedure and the burn-in procedure, the method comprising:
copying the monitor procedure from the external storage medium to the electronic device through the host computer;
activating the monitor procedure to monitor the burn-in procedure through the host computer;
activating the burn-in procedure for the electronic device through the monitor procedure stored in the electronic device;
determining a state of the burn-in procedure; and
outputting a monitor result corresponding to the state of the burn-in procedure.

2. The method of claim 1, wherein the step of determining the state of the burn-in procedure further comprises:
testing at least one process of internal operation of the electronic device during the burn-in procedure;
determining whether the at least one process is abnormal;
determining whether the burn-in procedure is finished; and
generating the monitor result corresponding to the state of the burn-in procedure.

3. The method of claim 2, wherein the step of generating the monitor result further comprises:
determining the burn-in procedure is successfully complete upon that the at least one process is normal; and
determining the burn-in procedure is failed upon that the at least one process is abnormal.

4. The method of claim 1, wherein outputting the monitor result further comprises:
displaying a first state when the burn-in procedure is normally operative.

5. The method of claim 3, wherein outputting the monitor result further comprises:
displaying a second state when the burn-in procedure is successfully complete.

6. The method of claim 3, wherein outputting the monitor result further comprises:
displaying a third state when the burn-in procedure is failed or the burn-in procedure is not activated.

7. A storage medium having stored thereon instructions that, when executed by a processor, causing the processor to perform a method for monitoring a burn-in procedure of an electronic device, the electronic device connected with a host computer, and an external storage device storing a monitor procedure and the burn-in procedure, wherein the method comprises:
copy the monitor procedure from the external storage medium to the electronic device through the host computer;
activate the monitor procedure to monitor the burn-in procedure through the host computer;
activate the burn-in procedure for the electronic device through the monitor procedure stored in the electronic device;
determine a state of the burn-in procedure; and
output a monitor result corresponding to the state of the burn-in procedure.

8. The storage medium of claim 7, wherein the step of determine the state of the burn-in procedure further comprises:
test at least one process of internal operation of the electronic device during the burn-in procedure;
determine whether the at least one process is abnormal;
determine whether the burn-in procedure is finished; and
generate the monitor result corresponding to the state of the burn-in procedure.

9. The storage medium of claim 8, wherein the step of generate the monitor result further comprises:
determine the burn-in procedure is successfully complete upon that the at least one process is normal; and
determine the burn-in procedure is failed upon that the at least one process is abnormal.

10. The storage medium of claim 7, wherein outputting the monitor result further comprises:
display a first state when the burn-in procedure is normally operative.

11. The storage medium of claim 9, wherein outputting the monitor result further comprises:
display a second state when the burn-in procedure is successfully complete.

12. The storage medium of claim 9, wherein outputting the monitor result further comprises:
display a third state when the burn-in procedure is failed or the burn-in procedure is not activated.
